(19) United States
(12) Patent Application Publication
(10) Pub. No.: US 2018/0315945 A1
(43) Pub. Date: Nov. 1, 2018

(54) CHARGE GENERATION LAYER, TANDEM OLED DEVICE AND DISPLAY SCREEN

(71) Applicant: Wuhan China Star Optoelectronics Technology Co., Ltd., Wuhan City (CN)

(72) Inventor: Xu Wang, Wuhan City (CN)

(21) Appl. No.: 15/551,290

(22) PCT Filed: Jun. 14, 2017
(86) PCT No.: PCT/CN2017/088323

§ 371 Date: Aug. 16, 2017

(30) Foreign Application Priority Data
Apr. 27, 2017 (CN) 201710288524.9

(51) Int. Cl. H01L 51/52; H01L 51/50; H01L 51/56; H01L 27/32

(52) U.S. Cl. CPC H01L 51/52; H01L 51/5048; H01L 2251/53; H01L 27/3209; H01L 2251/301; H01L 51/56

(57) ABSTRACT

The present invention provides a charge generation layer, a tandem OLED device and a display screen. The charge generation layer of the present invention consists of organic-inorganic hybrid perovskite material, a structural formula of which is ABX₃, wherein A is an organic amino group, B is 4^{th} main group metal ion or transition metal ion, X is a halogen element or a combination of a variety of halogen elements. The organic-inorganic hybrid perovskite material has not only a great carrier transporting capability but also further has a property with a higher optical absorption coefficient, and can emit a light longer than excitation light wavelength, and thus further can possess an effect on light color conversion in the tandem OLED device, thereby being beneficial to raising the performance of the tandem OLED device, lowering cost, and simplifying manufacturing process.

### FIELD OF THE INVENTION

The present invention relates to a flat display field, and more particular to a charge generation layer, a tandem OLED device and a display screen.

### BACKGROUND OF THE INVENTION

At the present, organic light-emitting diode (OLED) devices have been broadly applied in flat panel display and solid-state lighting etc., in various fields for daily life. Among them, OLED display technology, which is a flat panel display technology with extremely high development prospect, has greatly excellent display performances, especially in solid-state self-illumination, simplified structure, ultra thin thickness, fast response speed, wide viewing angle, low power consumption, accomplishable flexible display etc. properties, honored as ‘dreamlike display’, in addition that their production equipment investment is far less than that of liquid crystal display screen (Liquid Crystal Display, LCD), and thus is in favor with a number of large display factories, as now to be a main force of third-generation display device in display technical field. In recent years, wearable type electronic apparatus employing OLED screen, such as smart watch, smart bracelet, smart glasses and so forth, is more and more popular among consumers.

In a large variety of OLED device structures, a tandem OLED device with higher current efficiency can operate at lower current density, and lower current driving can also extend lifespan of the OLED device, so as to be applied for commercialized product. The tandem OLED device, does not only has device producing monochromatic luminescence but also can realize color mixing to acquire different required colors to satisfy different applications by connecting different light-emitting units with different colors. The most typical manner is connecting trichromatic light-emitting units having red (R), green (G) and blue (B), or connecting complementary-color light-emitting unit having blue and yellow (Y) for accomplishing OLED device emitting white (W) light. For example, a RGBW-based pixel array can be made so as to accomplish a panel having higher brightness, lower power consumption, higher resolution, or acting as a backlight for LCD.

To accomplish a tandem OLED, it is required to include charge generation layer within the device structure, and to have high efficient charge generation, charge transport and charge injection properties. The charge generation layer works in a function of connecting the neighboring light-emitting units in the tandem OLED device, and for the neighboring light-emitting units, generating, injecting, and transporting carriers to the light-emitting units. Briefly speaking, the function of the charge generation layer is: generating carriers, transporting carriers and injecting carriers. It is a significant issue how to make the charge generation layer generate carriers efficiently, transport carriers rapidly and inject carriers effectively, for achieving a high-performance tandem OLED device.

The efficiency of the OLED is directly related with the number of excitons formed by recombining holes and electrons. The more the number of photons emitted after the number of the excitons inactivates the more. In the traditional OLED device, a hole and an electron injected from positive electrode and negative electrode respectively can be recombined to form only one exciton. However, in tandem OLED device, such as a tandem OLED device containing two light-emitting units, a hole and an electron injected from positive electrode and negative electrode can form two excitons respectively with electrons and holes generated from the charge generation layer. Thus, the more the number of light-emitting units are stacked increasingly, the higher the efficiency of tandem OLED device can be increased in multiple. But the more the light-emitting units are device-stacked, the higher the driving voltage of the tandem OLED device is raised.

Presently, charge generation layers from doping to non-doping all were introduced, which are approximately classified as follows: (1) n-doped organic layer/inorganic metal oxide, such as Alq₃:Mg/WO₃, Bphen:Li/MoO₃, BCP:Li/V₂O₅ and BCP:Cs/V₂O₅; (2) n-doped organic layer/organic layer, such as Alq₃:Li/HAT-CN; (3) n-doped organic layer/p-doped organic layer, such as BPhen:Cs/NPB:F4-TCNQ, Alq₃:Li/NPB:FeCl₃, TPBi:Li/NPB:FeCl₃ and Alq₃:Mg/m-MTDATA:F4-TCNQ; (4) non-doped type, such as F₁₆CuPc/CuPc and Al/WO₃/Au. However, the tandem OLED device using the aforementioned charge generation layer still has a drawback of very high voltage. Thus, how to provide a highly efficient charge generation layer structure and material, thereby achieving high efficiency tandem OLED device, is very important.

Besides, in light path of the traditional tandem OLED device, light emitted from a light-emitting unit would pass through charge generation layer. Especially for white-light tandem OLED device, it is required to ensure that the charge generation layer has good transmittance, so as to avoid the mixing of lights emitted from several light-emitting units, which cannot form white light. Therefore, in the traditional tandem OLED device, charge generation layer cannot illuminate by itself, such that a lot of light-emitting units are required to illuminate and mix lights for generating white light. However, material lifespan of various light-emitting units are different, their long-time usage would readily result in color shifts, and more light-emitting units will occupy more evaporation sources, thereby causing a longer manufacturing process time.

### SUMMARY OF THE INVENTION

An objective of the present invention is to provide a charge generation layer, consisting of organic-inorganic hybrid perovskite materials, which has not only high carrier mobility, but can also emit light under light excitation to take an effect on light color conversion, thereby being beneficial to raising the performance of the tandem OLED device, lowering cost, and simplifying manufacturing process.

An objective of the present invention is to provide a tandem OLED device employing the aforementioned charge generation layer, which is beneficial to carrier transporting, and the charge generation layer further has an effect on light color conversion, thereby being capable of effectively enhancing device performance, lowering cost, and simplifying manufacturing process.

Another objective of the present invention is to provide a display screen employing the aforementioned tandem OLED device, which possesses a higher performance, lower cost, and simplified manufacturing process.

To accomplish the aforementioned objective, the present invention provides a charge generation layer consisting of organic-inorganic hybrid perovskite material;

A structural formula of said organic-inorganic hybrid perovskite material is ABX₃, wherein A is an organic amino group, B is 4^{th} main group metal ion or transition metal ion, X is a halogen element or a combination of a variety of halogen elements.

Said charge generation layer possesses a structure comprising n-type layer and p-type layer disposed in device stacks;

the organic-inorganic hybrid perovskite material that said charge generation layer consists of exists in one of said n-type layer and the p-type layer.

Said organic-inorganic hybrid perovskite material exists in said n-type layer or p-type layer in accordance with one of the following three manners:

(I) the entire layer material of said n-type layer or p-type layer is said organic-inorganic hybrid perovskite material;

(II) said organic-inorganic hybrid perovskite material acting as dopant is doped into said n-type layer or p-type layer; and

(III) said organic-inorganic hybrid perovskite material is electrically doped to form said n-type layer or p-type layer.

A is any one of alkylamine, aromatic amines and diamine.

B is any one of Pb²⁺, Ge²⁺, Sn²⁺, Cu²⁺, Ni²⁺, Co²⁺, Fe²⁺, Mn²⁺, and Eu²⁺;

X is any one of Cl, Br and I, or,

X is a combination of a variety of halogen elements, a structural formula of which is —ClₓBr_{y}I_{z}, wherein x+y+z=3.

The present invention further provides a tandem OLED device, which comprises n light-emitting units disposed in device stacks, and n−1 layer-interval charge generation layers, wherein nn≥2;

wherein one of said layer-interval charge generation layers disposed between each two neighboring light-emitting units, and at least one of the layer-interval charge generation layers is said charge generation layer.

An emission peak wavelength of at least one of the light-emitting unit is shorter than an emission peak wavelength of said organic-inorganic hybrid perovskite material.

An emission spectrum of at least one of the light-emitting units overlaps with the absorption spectrum of said organic-inorganic hybrid perovskite material.

The present invention further provides a display screen which comprises the aforementioned tandem OLED device.

The beneficial effects of the present invention are that: the charge generation layer of the present invention consists of organic-inorganic hybrid perovskite material. A structural formula of said organic-inorganic hybrid perovskite material is ABX₃, wherein A is an organic amino group, B is 4^{th} main group metal ion or transition metal ion, X is a halogen element or a combination of a variety of halogen elements; said organic-inorganic hybrid perovskite material has not only a great carrier transporting capability but has also a property of a higher optical absorption coefficient, which can emit light longer than excitation light wavelength, and thus further can possess an effect on light color conversion in the tandem OLED device, thereby being beneficial to raising the performance of the tandem OLED device, lowering cost, and simplifying manufacturing process. The tandem OLED device of the present invention, employing the aforementioned charge generation layer, is beneficial to carrier transporting. And the charge generation layer further possesses an effect on light color conversion, thereby being capable of effectively enhancing device performance, lowering cost, simplifying manufacturing process. A display screen of the present invention, employing the aforementioned tandem OLED device, possesses a higher performance, a lower cost, and a simplified manufacturing process.

For better realizing the characteristic and the technical context of the present invention, please refer to the detailed description in regard to the present invention with the accompanying drawings, however, the accompanying drawings just for reference and explanation but not for limitation to the present invention.

### BRIEF DESCRIPTION OF THE DRAWINGS

The technical solution and the beneficial effects of the present invention are best understood from the following detailed description with reference to the accompanying figures and embodiments.

In drawings,

FIG. 1 is a structurally schematic diagram of a charge generation layer of the present invention;

FIG. 2 is a structurally schematic diagram of the tandem OLED device of the present invention when emitting white light;

FIG. 3 is another structurally schematic diagram of the tandem OLED device of the present invention when emitting white light; and

FIG. 4 is another structurally schematic diagram of the tandem OLED device of the present invention when emitting white light.

### DETAILED DESCRIPTION OF PREFERRED EMBODIMENTS

For better explaining the technical solution and the effect of the present invention, the present invention will be further described in detail with the accompanying drawings and the specific embodiments.

An organic-inorganic hybrid perovskite material has a high potential of acting as charge generation layer material in a tandem OLED device owing to its great carrier transporting capability. Besides, the organic-inorganic hybrid perovskite material has a higher optical absorption coefficient such that this property can be utilized to accomplish a function of light color conversion, and to emit a light longer than excitation light wavelength, thereby achieving an objective of light color adjustment. This can decrease a quantity of light-emitting units of the tandem OLED device, or can decrease the kinds of luminous materials in use, and shorten a manufacturing process time. In aspect of film layer preparation, the organic-inorganic hybrid perovskite material can not only form film by solution preparation but further can also form film by vacuum thermal evaporation method, so its manufacturing process compatibility is excellent.

Based on an excellent performance of the aforementioned organic-inorganic hybrid perovskite material, the present invention firstly provides a charge generation layer consisting of organic-inorganic hybrid perovskite material. A structural formula of said organic-inorganic hybrid perovskite material is ABX₃, wherein A is an organic amino group, B is 4^{th} main group metal ion or transition metal ion, and X is a halogen element or a combination of a variety of halogen elements.

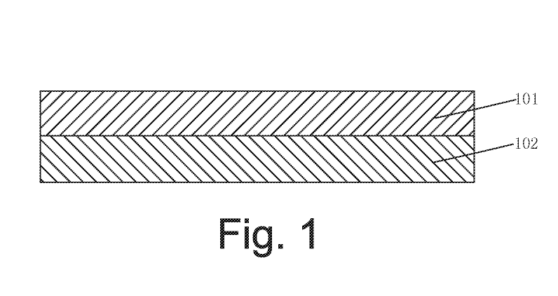

Specifically, as shown in FIG. 1, the charge generation layer of the present invention has a structure which comprises n-type layer 101 and p-type layer 102 disposed in device stacks; the organic-inorganic hybrid perovskite material in said charge generation layer only exists in one of said n-type layer 101 and p-type layer 102. An existing formation of said organic-inorganic hybrid perovskite material in the charge generation layer can be pure organic-inorganic hybrid perovskite material as the entire layer material for the n-type layer 101 or p-type layer 102, and can also act as a dopant doped into the n-type layer 101 or p-type layer 102, and further can implement electrical doping for a layer consisting of the organic-inorganic hybrid perovskite material.

It is required to specify that, in the charge generation layer of the present invention, said n-type layer 101 and p-type layer 102 can bottom-to-top sequentially disposed in device stacks, and can also top-to-bottom sequentially disposed in device stacks, their concrete structures is determined in accordance with a structure (a normal type structure or an inverted type structure) of the tandem OLED device where said n-type layer 101 and p-type layer 102 are allocated, when said charge generation layer is concretely embodied.

Specifically, in a structural formula of said organic-inorganic hybrid perovskite material, A can be any one of alkylamine, aromatic amines and diamine; B can be any one of 4^{th} main group metal ions Pb²⁺, Ge²⁺ and Sn²⁺, B can also be any one of transition metal ions Cu²⁺, Ni²⁺, Co²⁺, Fe²⁺, Mn²⁺ and Eu²⁺; X can be any one of halogen elements Cl, Br and I, and X can also be a combination of a variety of halogen elements, which has the following structural formula: —ClₓBr_{y}I_{z}, wherein x+y+z=3.

The charge generation layer of the present invention consists of the organic-inorganic hybrid perovskite material which has not only a great carrier transporting capability but also further has a property of a higher optical absorption coefficient, and can emit a light longer than excitation light wavelength, so as to further be capable of possessing an effect on light color conversion in the tandem OLED device, thereby being beneficial to raising the performance of the tandem OLED device, lowering cost, and simplifying manufacturing process.

Based on the aforementioned charge generation layer, the present invention further provides a tandem OLED device, which comprises n light-emitting units 110 disposed in device stacks, and n−1 layer-interval charge generation layers 120, wherein n≥2;

wherein one of said layer-interval charge generation layers 120 disposed between each two neighboring light-emitting units 110. And at least one of the layer-interval charge generation layers 120 is as the aforementioned charge generation layer.

Specifically, to accomplish light color conversion function of the charge generation layer, the tandem OLED device of the present invention has at least one light-emitting unit 110, the emission peak wavelength of which is shorter than the emission peak wavelength of said organic-inorganic hybrid perovskite material; and an emission spectrum of at least one light-emitting unit 110 overlaps with an absorption spectrum of said organic-inorganic hybrid perovskite material. For example, in the tandem OLED device, a light-emitting unit 110 emits blue light, and then an absorption wave band of said organic-inorganic hybrid perovskite material also overlaps with an emission light of the light-emitting unit 110, and under excitation of blue light, emits light with a longer wave band, like green light, yellow-orange light, or red light.

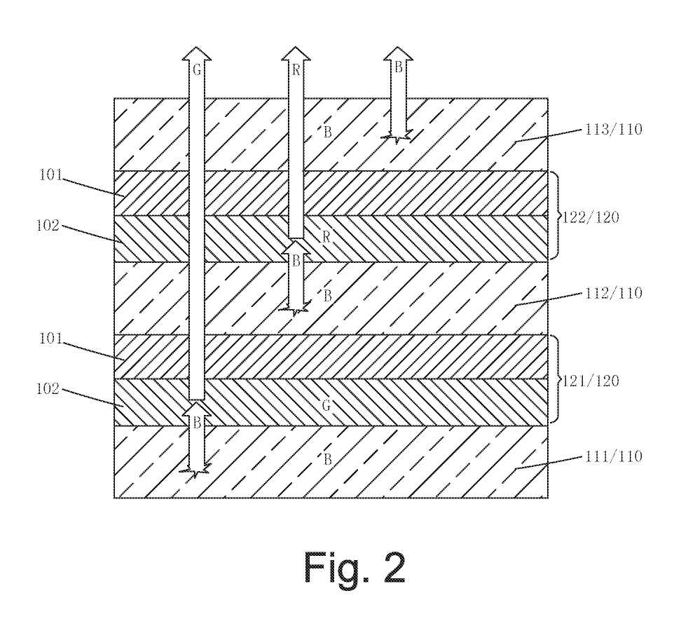

As shown in FIG. 2, if the tandem OLED device of the present invention is a tandem OLED device that emits white light, said tandem OLED device can be a structure as shown in FIG. 2. In said tandem OLED device, a quantity of said light-emitting units 110 is three, which are a first light-emitting unit 111, a second light-emitting unit 112, and a third light-emitting unit 113 respectively arranged from bottom to top, and then said layer-interval charge generation layers 120 are two, which are a first layer-interval charge generation layer 121 and a second layer-interval charge generation layer 122 respectively arranged from bottom to top, and said first layer-interval charge generation layer 121 and second layer-interval charge generation layer 122 all are the aforementioned charge generation layer consisting of the organic-inorganic hybrid perovskite material, wherein said first light-emitting unit 111, said second light-emitting unit 112, and said third light-emitting unit 113 all are blue-light light-emitting units that emit blue light, whereas after said first layer-interval charge generation layer 121 emits green light after absorbing blue light, said second layer-interval charge generation layer 122 emits red light after absorbing blue light, thereby facilitating the whole tandem OLED device emitting white light. The aforementioned tandem OLED device as shown in FIG. 2, which emits white light, in contrast with the traditional tandem OLED device employing red-light, green-light, blue light light-emitting units to generate white light, has light-emitting units 110 all which are blue-light light-emitting units, and omit red-light light-emitting unit and green-light light-emitting unit. Thus, in the tandem OLED device, the material lifespan of the light-emitting units 110 are principally consistent. It only needs to occupy lesser evaporation sources in manufacturing process, thereby saving manufacturing process time.

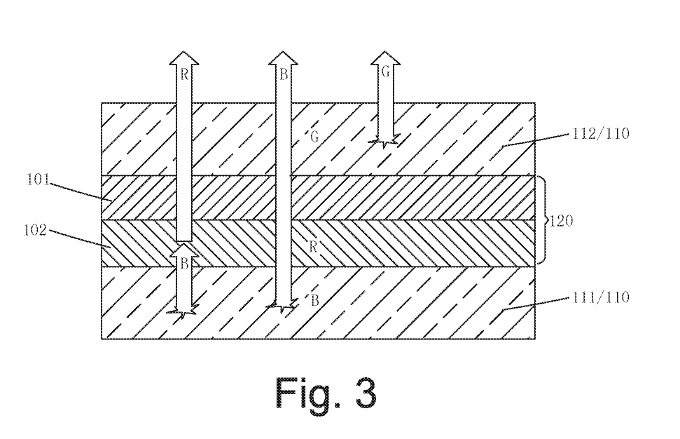

Alternatively, as shown in FIG. 3, while the tandem OLED device of the present invention is a tandem OLED device emitting white light, said tandem OLED device can also has a structure as shown in FIG. 3. In said tandem OLED device, a quantity of said light-emitting unit 110 is two, which are a first light-emitting unit 111 and a second light-emitting unit 112 respectively from bottom to top, and then said layer-interval charge generation layer 120 is one as the aforementioned charge generation layer consisting of the organic-inorganic hybrid perovskite material, wherein said first light-emitting unit 111 and said second light-emitting unit 112 respectively are one of the blue-light light-emitting unit and green-light light-emitting unit, whereas said layer-interval charge generation layer 120 emits red light after absorbing blue light or green light, thereby facilitating the whole tandem OLED device emitting white light. The aforementioned tandem OLED device as shown in FIG. 3, which emits white light, in contrast with the traditional tandem OLED device employing red-light, green-light, blue-light light-emitting units to generate white light, omits red-light light-emitting unit, decreases a quantity of the light-emitting units, and saves manufacturing process time.

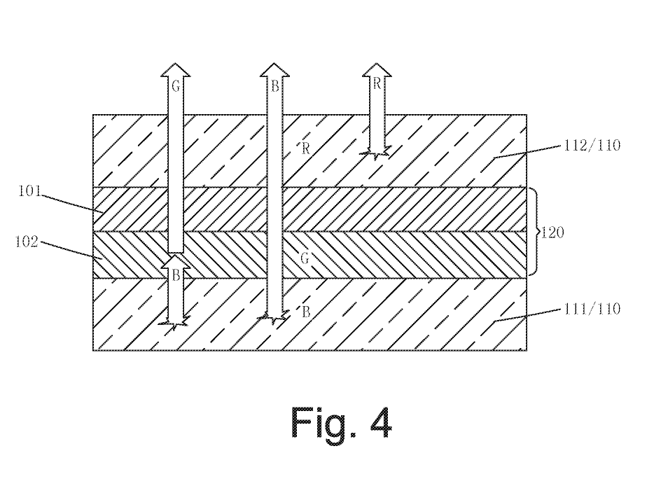

Further alternatively, as shown in FIG. 4, when the tandem OLED device of the present invention is a tandem OLED device emitting white light, said tandem OLED device can also has a structure therein as shown in FIG. 4. In said tandem OLED device, a quantity of said light-emitting unit 110 is two, which are a first light-emitting unit 111 and a second light-emitting unit 112 respectively from bottom to top, and then said layer-interval charge generation layers 120 is one as the aforementioned charge generation layer consisting of the organic-inorganic hybrid perovskite material, wherein said first light-emitting unit 111 and said second light-emitting unit 112 are respectively blue-light light-emitting unit and red-light light-emitting unit, whereas said layer-interval charge generation layers 120 emits green light after absorbing blue light, thereby facilitating the whole tandem OLED device emitting white light. The aforementioned tandem OLED device as shown in FIG. 3, which emits white light, in contrast with the traditional white-light-emission tandem OLED device employing red-light, green-light, blue light light-emitting units to generate white light, omits green-light light-emitting unit, decreases a quantity of the light-emitting units, and saves manufacturing process time.

The tandem OLED device of the present invention, employing the aforementioned charge generation layer consisting of the organic-inorganic hybrid perovskite material, is beneficial to carrier transporting, and said charge generation layer further can possess an effect on light color conversion, thereby being capable of effectively enhancing device performance, and appropriately reducing a quantity and kinds of the light-emitting units 110, lowering cost, and simplifying manufacturing process.

Based on the aforementioned tandem OLED device, the present invention further provides a display screen, which comprises the aforementioned OLED device.

For example, said display screen is a display screen based on RGBW pixel array, which comprises a plurality of red sub-pixel unit, green sub-pixel unit, blue sub-pixel unit, and white sub-pixel unit arranged in array, wherein light-emitting device in said white sub-pixel unit can employ the aforementioned tandem OLED device.

In conclusion, the charge generation layer of the present invention consists of the organic-inorganic hybrid perovskite material. A structural formula of said organic-inorganic hybrid perovskite material is ABX₃, wherein A is an organic amino group, B is 4th main group metal ion or transition metal ion, X is a halogen element or a combination of a variety of halogen elements; said organic-inorganic hybrid perovskite material has not only a great carrier transporting capability but also further has a property with a higher optical absorption coefficient, and can emit a light longer than excitation light wavelength, and thus further can possess an effect on light color conversion in the tandem OLED device, thereby being beneficial to raising the performance of the tandem OLED device, lowering cost, and simplifying manufacturing process. The tandem OLED device of the present invention, which employs the aforementioned charge generation layer, is beneficial to carrier transporting, and the charge generation layer further can possess an effect on light color conversion, thereby being capable of effectively enhancing device performance, lowering cost, and simplifying manufacturing process. The display screen of the present invention, which employs the aforementioned tandem OLED device, has a higher performance, lower cost, and simplified manufacturing process.

As above mentioned, in accordance with technical embodiments and technical solution of the present invention, to any persons who are ordinary skilled in the art, other related change or variances can be made which should be covered by the protected scope of the subject claims attached below by the present invention.

What is claimed is:

1. A charge generation layer, which consists of organic-inorganic hybrid perovskite material;
a structural formula of said organic-inorganic hybrid perovskite material is ABX₃, wherein A is an organic amino group, B is 4^{th} main group metal ion or transition metal ion, and X is a halogen element or a combination of a variety of halogen elements.

2. Said charge generation layer as claimed in claim 1, wherein a structure of said charge generation layer comprises n-type layer and p-type layer disposed in device stacks; and
said charge generation layer consisting of organic-inorganic hybrid perovskite material which exists in one of said n-type layer and p-type layer.

3. Said charge generation layer as claimed in claim 2, wherein said organic-inorganic hybrid perovskite material exists in said n-type layer or p-type layer in accordance with one of the following three manners:
(I) the entire layer material of said n-type layer or p-type layer is said organic-inorganic hybrid perovskite material;
(II) said organic-inorganic hybrid perovskite material acts as a dopant doped into said n-type layer or p-type layer; and
(III) said organic-inorganic hybrid perovskite material forms said n-type layer or p-type layer after electrically doped.

4. Said charge generation layer as claimed in claim 1, wherein A is any one of alkylamine, aromatic amines and diamine.

5. Said charge generation layer as claimed in claim 1, wherein B is any one of Pb²⁺, Ge²⁺, Sn²⁺, Cu²⁺, Ni²⁺, Co²⁺, Fe²⁺, Mn²⁺ and Eu²⁺.

6. Said charge generation layer as claimed in claim 1, wherein X is any one of Cl, Br and I, or
X is a combination of a variety of halogen elements, a structural formula of which is —ClₓBr_{y}I_{z}, wherein x+y+z=3.

7. A tandem OLED device, comprising n light-emitting units and n−1 layer-interval charge generation layers disposed in device stacks, wherein n≥2;
wherein one of said layer-interval charge generation layers is disposed between each two neighboring light-emitting units, and at least one of the layer-interval charge generation layers is said charge generation layer as claimed in claim 1.

8. Said tandem OLED device as claimed in claim 7, wherein an emission peak wavelength of at least one of the light-emitting units is shorter than an emission peak wavelength of said organic-inorganic hybrid perovskite material.

9. Said tandem OLED device as claimed in claim 7, wherein an emission spectrum of at least one of the light-emitting units overlaps with an absorption spectrum of said organic-inorganic hybrid perovskite material.

10. A display screen, comprising said tandem OLED device as claimed in claim 7.
